(19) United States
(12) Patent Application Publication
(10) Pub. No.: US 2016/0065201 A1
(43) Pub. Date: Mar. 3, 2016

(54) REFERENCE CURRENT SETTING CIRCUIT

(71) Applicant: Kabushiki Kaisha Toshiba, Tokyo (JP)

(72) Inventors: Taisuke Ishizawa, Yokohama Kanagawa (JP); Hiroshi Yoshino, Yokohama Kanagawa (JP)

(21) Appl. No.: 14/617,592

(22) Filed: Feb. 9, 2015

(30) Foreign Application Priority Data
Aug. 28, 2014 (JP) 2014-174364

(51) Int. Cl. H03K 17/16; H03K 3/012

(52) U.S. Cl. CPC H03K 17/161; H03K 3/012

(57) ABSTRACT

A reference current setting circuit according to one embodiment includes a first terminal, a first current mirror circuit, a second current mirror circuit, and a third current mirror circuit. The first terminal is connected to a ground potential via a first resistor. The first current mirror circuit includes a first transistor with a source connected to a reference voltage and a drain serving as a first input terminal, and a second transistor with a source connected to the first terminal and a drain serving as a first output terminal, the drain of the first transistor being connected to a gate of the first transistor and a gate of the second transistor.

### CROSS REFERENCE TO RELATED APPLICATION

This application is based upon and claims the benefit of priority from the prior Japanese Patent Application No. 2014-174364, filed on Aug. 28, 2014, the entire contents of which are incorporated herein by reference.

### FIELD

Embodiments described herein relate to a reference current setting circuit.

### BACKGROUND

As a circuit to create a constant current as a reference current, there has been heretofore used a reference current setting circuit which includes an operational amplifier, a MOS transistor, and a resistor. In the reference current setting circuit, a current to flow through the current output MOS transistor flows through the resistor to create a feedback voltage, and the operational amplifier controls a gate voltage of the current output MOS transistor such that the feedback voltage can become equal to the reference voltage. Under the control of the gate voltage, the current output MOS transistor outputs a constant reference current.

In some cases, the abovementioned configuration uses an externally connected resistor to avoid an influence due to variations of resistance values. In this case, the configuration is provided with an external terminal to connect the externally connected resistor.

However, when the external terminal is provided, a parasitic capacitance, such as a pad capacitance, a bonding wire capacitance, a lead capacitance, and a substrate capacitance, is generated at the external terminal. An influence of the parasitic capacitance lowers a phase margin for a negative feedback circuit that is formed between the input and the output of the operational amplifier. This causes a problem in that the negative feedback circuit oscillates when a high frequency noise propagates to the external terminal for connecting the resistor, for example.

### BRIEF DESCRIPTION OF THE DRAWINGS

FIG. 1 is a circuit diagram illustrating a configuration of a reference current setting circuit according to a first embodiment;

FIG. 2 is a diagram for explaining calculation of an open loop gain with respect to input of an alternating-current signal in the reference current setting circuit according to the first embodiment;

FIG. 3 is a frequency characteristic chart of a relation, which is obtained by simulation, between the magnitude of the parasitic capacitance and fluctuations of a gain and a phase in the reference current setting circuit according to the first embodiment;

FIG. 4 is a circuit diagram illustrating a configuration of a reference current setting circuit according to a second embodiment;

FIG. 5 is a waveform chart of the power supply voltage dependence, which is obtained by simulation, of an output reference current from the reference current setting circuit according to the second embodiment; and

FIGS. 6A to 6C illustrate current mirror circuits in a modification, FIG. 6A illustrates a Wilson-type current mirror circuit, FIG. 6B illustrates a cascode-type current mirror circuit, and FIG. 6C illustrates a high-accuracy Wilson-type current mirror circuit.

### DETAILED DESCRIPTION

A reference current setting circuit according to one embodiment includes a first terminal, a first current mirror circuit, a second current mirror circuit, and a third current mirror circuit. The first terminal is connected to a ground potential via a first resistor. The first current mirror circuit includes a first transistor with a source connected to a reference voltage and a drain serving as a first input terminal, and a second transistor with a source connected to the first terminal and a drain serving as a first output terminal, the drain of the first transistor being connected to a gate of the first transistor and a gate of the second transistor. The second current mirror circuit includes a second input terminal and second to fourth output terminals, the second input terminal connected to the first output terminal, the second output terminal connected to the first input terminal, and is configured to be supplied with a first voltage power supply and to output a reference current from the third output terminal. The third current mirror circuit includes a fifth output terminal connected to the reference voltage source and a third input terminal connected to the fourth output terminal.

Hereinafter, embodiments will be further described with reference to the drawings. In the drawings, the same reference numerals indicate the same or the similar portions.

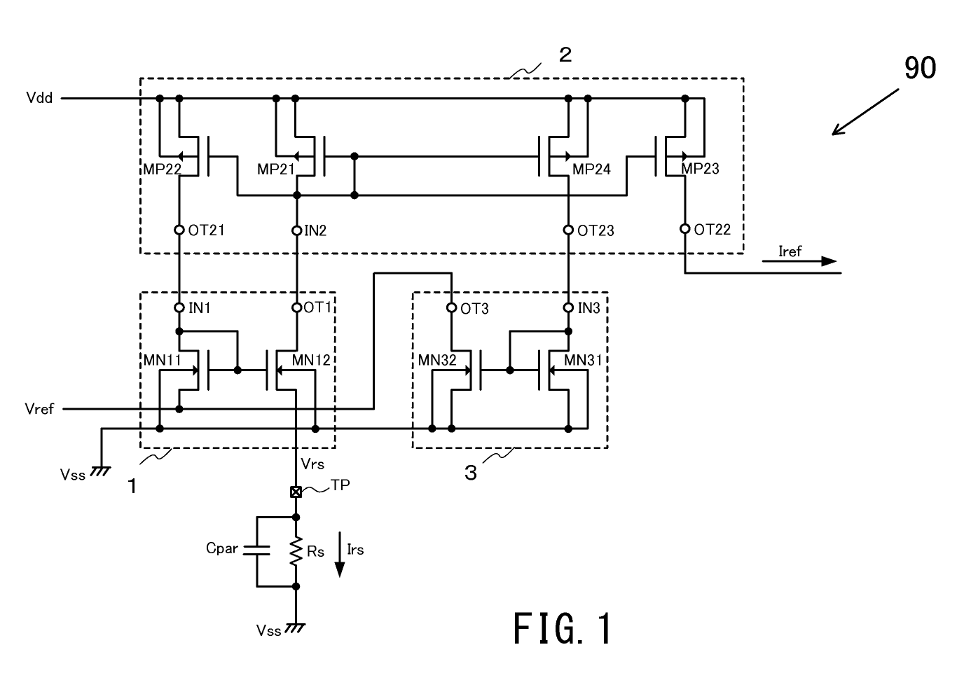

A reference current setting circuit according to a first embodiment will be described with reference to the drawings. FIG. 1 is a circuit diagram illustrating a configuration of the reference current setting circuit.

As shown in FIG. 1, a reference current setting circuit 90 includes a current mirror circuit 1, a current mirror circuit 2, a current mirror circuit 3, an external terminal TP, and an external resistor Rs.

The external terminal TP (first terminal) is connected to a ground potential Vss via the external resistor Rs (first resistor). The external resistor Rs is an externally connected resistor.

The current mirror circuit 1 (first current mirror circuit) includes an N-channel MOS transistor MN11 (first transistor) and an N-channel MOS transistor MN12 (second transistor). A drain of the N-channel MOS transistor MN11 serves as an input terminal IN1 (first input terminal), and a drain of the N-channel MOS transistor MN12 serves as an output terminal OT1 (first output terminal). Note that, the MOS (Metal Oxide Semiconductor) transistor is also referred to as a MOSFET (Metal Oxide Semiconductor Field Effect Transistor).

The current mirror circuit 2 (second current mirror circuit) includes a P-channel MOS transistor MP21 (third transistor), a P-channel MOS transistor MP22 (fourth transistor), a P-channel MOS transistor MP23 (fifth transistor), and a P-channel MOS transistor MP24 (sixth transistor). A drain of the P-channel MOS transistor MP21 serves as an input terminal IN2 (second input terminal), and the input terminal IN2 is connected to the output terminal OT1 of the current mirror circuit 1. A drain of the P-channel MOS transistor MP22 serves as an output terminal OT21 (second output terminal), and the output terminal OT21 is connected to the input terminal IN1 of the current mirror circuit 1. A drain of the P-channel MOS transistor MP23 serves as an output terminal OT22 (third output terminal), and a reference current Iref is outputted from the output terminal OT22. A drain of the P-channel MOS transistor MP24 serves as an output terminal OT23 (fourth output terminal).

The current mirror circuit 3 (third current mirror circuit) includes an N-channel MOS transistor MN31 (seventh transistor) and an N-channel MOS transistor MN32 (eighth transistor). A drain of the N-channel MOS transistor MN31 serves as an input terminal IN3 (third input terminal), and the input terminal IN3 is connected to the output terminal OT23 of the current mirror circuit 2. A drain of the N-channel MOS transistor MN32 serves as an output terminal OT3 (fifth output terminal), and the output terminal OT3 is connected to a reference voltage source Vref.

A parasitic capacitance Cpar such as a pad capacitance, a bonding wire capacitance, a lead capacitance, and a substrate capacitance is generated at the external terminal TP. Herein, the parasitic capacitance Cpar is illustrated so as to be connected in parallel with the external resistor Rs.

The N-channel MOS transistor MN11 that constitutes the current mirror circuit 1 has a source that is connected to the reference voltage source Vref, a back gate that is connected to the ground potential Vss, and the drain that is connected to a gate of the N-channel MOS transistor MN11 and a gate of the N-channel MOS transistor MN12. The N-channel MOS transistor MN12 has a source that is connected to the external terminal TP and a back gate that is connected to the ground potential Vss.

The external resistor Rs is connected to the external terminal TP. Accordingly, the source of the N-channel MOS transistor MN12 is connected to the external resistor Rs via the external terminal TP.

A mirror ratio of the current mirror circuit 1 is set to 1. Specifically, a size (gate length, gate width) of the N-channel MOS transistor MN12 is set to be identical with a size (gate length, gate width) of the N-channel MOS transistor MN11. Accordingly, a current having the same magnitude as a current flowing through the N-channel MOS transistor MN11 flows through the N-channel MOS transistor MN12.

The P-channel MOS transistor MP21 that constitutes the current mirror circuit 2 has a source that is connected to a first voltage power supply Vdd, the drain that is connected to a gate of the P-channel MOS transistor MP21, a gate of the P-channel MOS transistor MP22, a gate of the P-channel MOS transistor MP23, and a gate of the P-channel MOS transistor MP24, and a back gate that is connected to the first voltage power supply Vdd. The P-channel MOS transistor MP22 has a source that is connected to the first voltage power supply Vdd and a back gate that is connected to the first voltage power supply Vdd. The P-channel MOS transistor MP23 has a source that is connected to the first voltage power supply Vdd, a back gate that is connected to the first voltage power supply Vdd, and the drain from which the reference current Iref is outputted. The P-channel MOS transistor MP24 has a source that is connected to the first voltage power supply Vdd and a back gate that is connected to the first voltage power supply Vdd.

A mirror ratio of the current mirror circuit 2 is set to 1. Specifically, sizes (gate lengths, gate widths) of the P-channel MOS transistor MP22, the P-channel MOS transistor MP23, and the P-channel MOS transistor MP24 are set to be identical with a size (gate length, gate width) of the P-channel MOS transistor MP21. Accordingly, a current having the same magnitude as a current flowing through the P-channel MOS transistor MP21 flows through the P-channel MOS transistor MP22, the P-channel MOS transistor MP23, and the P-channel MOS transistor MP24.

The current mirror circuit 2 causes a current having the same magnitude as a current having been inputted into the input terminal IN2 from the output terminal OT1 of the current mirror circuit 1 to be fed back positively to the input terminal IN1 of the current mirror circuit 1, from the output terminal OT21.

The output terminal OT23 is connected to the input terminal IN3 of the current mirror circuit 3. This allows the current mirror circuit 2 to input a current having the same magnitude as a current having been inputted into the input terminal IN2 from the output terminal OT1 of the current mirror circuit 1, into the input terminal IN3 of the current mirror circuit 3, from the output terminal OT23.

A current having the same magnitude as a current having been inputted into the input terminal IN2 from the output terminal OT1 of the current mirror circuit 1 is outputted from the output terminal OT22. The reference current Iref is outputted from the output terminal OT22.

The N-channel MOS transistor MN31 that constitutes the current mirror circuit 3 has a source that is connected to the ground potential Vss, a back gate that is connected to the ground potential Vss, and the drain that is connected to a gate of the N-channel MOS transistor MN31 and a gate of the N-channel MOS transistor MN32. The N-channel MOS transistor MN32 has a source that is connected to the ground potential Vss and a back gate that is connected to the ground potential Vss.

A mirror ratio of the current mirror circuit 3 is set to 1. Specifically, a size (gate length, gate width) of the N-channel MOS transistor MN32 is set to be identical with a size (gate length, gate width) of the N-channel MOS transistor MN31. Accordingly, a current having the same magnitude as a current flowing through the N-channel MOS transistor MN32 flows through the N-channel MOS transistor MN31.

The input terminal IN3 is connected to the output terminal OT23 of the current mirror circuit 2, and the output terminal OT3 is connected to the reference voltage source Vref. Accordingly, a current having the same magnitude as a current having been inputted into the input terminal IN3 from the current mirror circuit 2 flows through the output terminal OT3.

Next, an operation of the reference current setting circuit in the embodiment will be described.

Here, when a current that flows through the external resistor Rs connected to the external terminal TP is set as Irs, a voltage Vrs that appears at the external terminal TP is represented as Vrs=Irs×Rs by setting a resistance value of the external resistor Rs as Rs.

The current mirror circuit 1 adjusts the magnitude of a current flowing through the N-channel MOS transistor MN12 such that the voltage Vrs matches a reference voltage Vref1 of the reference voltage source Vref (to satisfy Vrs=Vref1).

As a result, the current Irs flows through the N-channel MOS transistor MN12. In this process, Irs=Vref1/Rs is obtained from Vrs=Vref1.

The current Irs is inputted into the input terminal IN2 of the current mirror circuit 2 from the output terminal OT1 of the current mirror circuit 1, and is fed back positively to the input terminal IN1 of the current mirror circuit 1 from the output terminal OT21 of the current mirror circuit 2.

As a result, the current mirror circuit 1 maintains the constant magnitude of the current Irs.

The current mirror circuit 2 outputs a current having the same magnitude as the current Irs as the reference current Iref, from the output terminal OT22. Accordingly, the reference current Iref is represented as Iref=Vref1/Rs.

As described above, the current mirror circuit 1 performs an operation to maintain the current Irs flowing through the external resistor Rs constant. The current Irs also flows through the reference voltage source Vref from the N-channel MOS transistor MN11. When the current flowing through the N-channel MOS transistor MN11 directly flows into the reference voltage source Vref, the reference voltage Vref1 may fluctuate.

In the embodiment, the current mirror circuit 3 is provided to prevent the reference voltage Vref1 from fluctuating. The current mirror circuit 3 allows a current flowing into the reference voltage source Vref from the current mirror circuit 1 to flow through the N-channel MOS transistor MN32 via the output terminal OT3 of the current mirror circuit 3.

As a result, the current is prevented to flow into the reference voltage source Vref. This can maintain the stability of the reference voltage Vref1.

The reference current Iref outputted from the reference current setting circuit 90 in the embodiment satisfies Iref=Vref1/Rs. Accordingly, the use of a high accuracy resistor as the external resistor Rs can enhance the accuracy of the reference current Iref.

The external terminal TP is provided to connect the external resistor Rs. Accordingly, the parasitic capacitance Cpar generated at the external terminal TP or a high frequency noise propagating through the external terminal TP may have an influence on a circuit operation.

In view of this, an open loop gain when an alternating-current signal is inputted into the external terminal TP is calculated, and an influence of the parasitic capacitance Cpar on the open loop gain will be described.

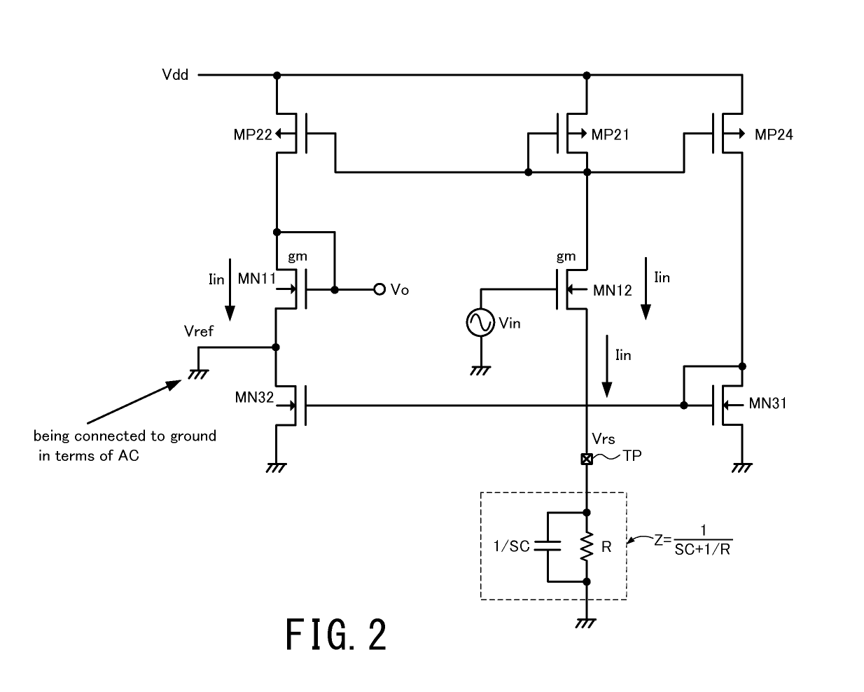

FIG. 2 is a circuit diagram used to calculate the open loop gain described above. Herein, an input Vin as an alternating-current signal is inputted into the gate of the N-channel MOS transistor MN12, and an output Vo is outputted from the gate of the N-channel MOS transistor MN11. The reference voltage source Vref as a direct-current voltage source is grounded in terms of alternating current.

Attention is focused on a current flowing through the N-channel MOS transistor MN12. When a voltage at the external terminal TP is set as Vrs and a mutual inductance of the N-channel MOS transistor MN12 is set as gm, a current Iin flowing through the N-channel MOS transistor MN12 is represented as Expression (1) using a gate-source voltage (Vin−Vrs) of the N-channel MOS transistor MN12.

Iin=gm(Vin−Vrs) Expression (1)

Attention is focused on a current flowing through the N-channel MOS transistor MN11. The N-channel MOS transistor MN11 has the same size as the N-channel MOS transistor MN12. Accordingly, the N-channel MOS transistor MN11 has a mutual inductance gm as same as that of the N-channel MOS transistor MN12, and a current Iin having the same magnitude as the current flowing through the N-channel MOS transistor MN12 flows through the N-channel MOS transistor MN11. The current Iin is represented as Expression (2) using a gate-source voltage Vo.

Iin=gm×Vo Expression (2)

Accordingly, with the Expression (1) and the Expression (2) described above, the current Iin is represented as Expression (3).

Vin−Vrs=Vo Expression (3)

The voltage Vrs at the external terminal TP is represented as Expression (4) by setting an impedance in a parallel circuit of the external resistor Rs and the parasitic capacitance Cpar as Z.

Vrs=Iin×Z Expression (4)

When Expression (2) is substituted into Expression (4), Expression (5) is obtained.

Vrs=gm×Vo×Z Expression (5)

When Expression (3) is substituted into Expression (5), Expression (6) is obtained.

Vin−(gm×Vo×Z)=Vo Expression (6)

Expression (7) is obtained from Expression (6).

Vin=(1+(gm×Z))×Vo Expression (7)

When an open loop gain Vo/Vin is calculated from Expression (7), Expression (8) is obtained.

Vo/Vin=1/(1+(gm×z)) Expression (8)

Herein, a resistance value of the external resistor Rs is set as R, and an impedance of the parasitic capacitance Cpar is set to 1/SC. When S=jω (ω: angular frequency) is satisfied, the impedance Z is represented as Expression (9).

Z=1/(SC+1/R)=R/(1+(SC×R)) Expression (9)

When Expression (9) is substituted into Expression (8), the open loop gain Vo/Vin is represented as Expression (10).

Vo/Vin=1/(1+gm×(R/(1+SC×R))=(1+SC×R)/(1+SC×R+gm×R) Expression (10)

In Expression (10), the terms (SC×R) that relate to the parasitic capacitance Cpar are included in both of the denominator and the numerator. Accordingly, it is understood that the terms (SC×R) have less influence on the open loop gain Vo/Vin because the denominator and numerator cancel each other out.

In other words, in the embodiment, it can be considered that input of an alternating-current signal into the external terminal TP causes the parasitic capacitance Cpar to have less influence on the circuit operation.

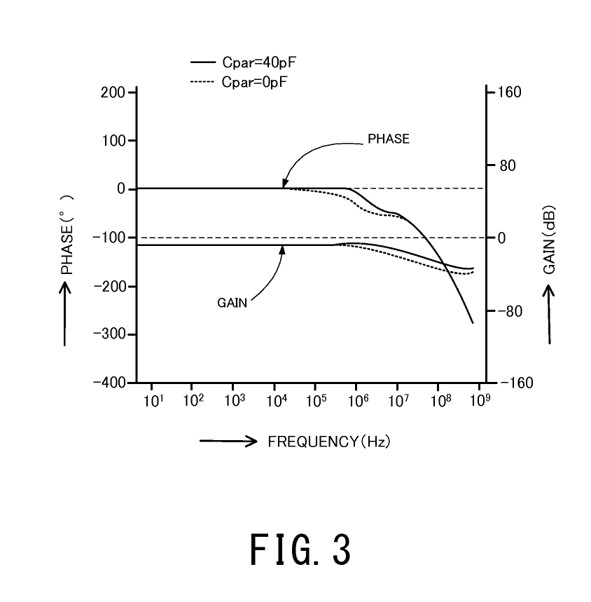

FIG. 3 illustrates a result, which is obtained by simulation, of an influence of the parasitic capacitance Cpar on a frequency characteristic of the reference current setting circuit 90. Herein, cases of Cpar=40 pF and Cpar=0 pF are illustrated.

As shown in FIG. 3, the parasitic capacitance Cpar have less influence on the frequency characteristics of the gain and the phase of the reference current setting circuit 90.

The reference current setting circuit 90 does not oscillate with a phase delay due to the parasitic capacitance Cpar because the gain is always 0 dB or less.

As described above, the embodiment can prevent a feedback circuit from oscillating even when a parasitic capacitance is generated at the external terminal to connect an external resistor because the current is fed back positively with the loop gain at one time by combining the current mirror circuits with the mirror ratio of 1.

Note that, MOS transistors in which a gate insulating film is configured to include a silicon oxide film are used as the transistors that constitute the current mirror circuits 1 to 3 in the embodiment, however, the embodiment is not necessarily limited the MOS transistors. A metal insulator semiconductor (MIS) transistor in which a gate insulating film is configured to include an ON film, an insulating film having a high dielectric constant, or the like may be used.

A reference current setting circuit according to a second embodiment will be described. In the first embodiment, a low first voltage Vdd1 at the first voltage power supply Vdd reduces a source-drain voltage of the N-channel MOS transistor MN12 that is connected to the output terminal OT1 of the current mirror circuit 1 accordingly to reduce a current to be flowed through the input terminal IN2 of the current mirror circuit 2. This also reduces a value of the reference current Iref that is outputted from the output terminal OT22 of the current mirror circuit 2. In the embodiment, a reference current setting circuit capable of preventing a value of the reference current Iref from being reduced regardless of the low first voltage Vdd1 at the first voltage power supply Vdd will be described with reference to the drawings. Hereinafter, the same reference numerals are assigned to the same constitute portions as the first embodiment, explanations thereof are omitted, and only different portions will be described.

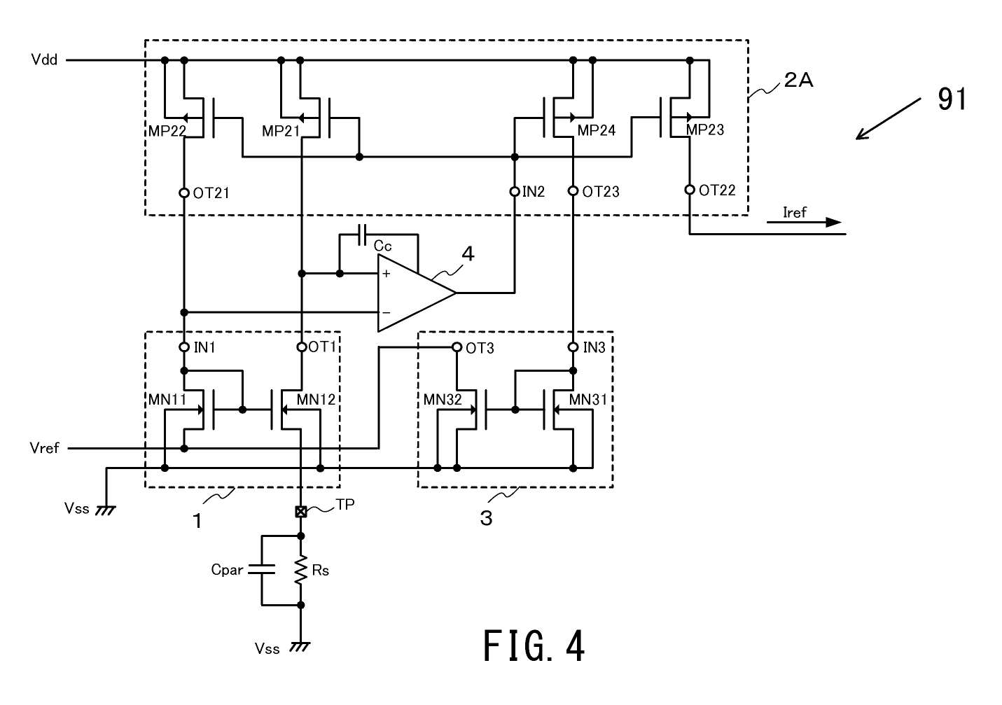

FIG. 4 is a circuit diagram illustrating a configuration of a reference current setting circuit.

As shown in FIG. 4, a reference current setting circuit 91 includes the current mirror circuit 1, a current mirror circuit 2A, the current mirror circuit 3, an operational amplifier 4, the external terminal TP, and the external resistor Rs. The operational amplifier 4 is interposed between the output terminal OT1 of the current mirror circuit 1 and the input terminal IN2 of the current mirror circuit 2A.

The operational amplifier 4 has a non-inverting input (+) terminal to which the output terminal OT1 of the current mirror circuit 1 is connected, an inverting input (−) terminal to which the input terminal IN1 of the current mirror circuit 1 is connected, and an output terminal that is connected to the input terminal IN2 of the current mirror circuit 2A. A capacitor Cc that is connected to the operational amplifier 4 is a phase compensation capacitor.

The input terminal IN2 of the current mirror circuit 2A is connected to the gates of the P-channel MOS transistor MP21, the P-channel MOS transistor MP22, the P-channel MOS transistor MP23, and the P-channel MOS transistor MP24, which is different from the current mirror circuit 2 in the first embodiment. The drain of the P-channel MOS transistor MP21 is connected to the output terminal OT1 of the current mirror circuit 1.

The output terminal OT21 to which the drain of the P-channel MOS transistor MP22 of the current mirror circuit 2A is connected is connected to the input terminal IN1 of the current mirror circuit 1. Accordingly, an output from the operational amplifier 4 is feed backed to the inverting input terminal via the P-channel MOS transistor MP22.

The operational amplifier 4 controls an output voltage such that the voltage at the inverting input terminal matches the voltage at the non-inverting input terminal. Accordingly, the inverting input terminal and the non-inverting input terminal of the operational amplifier 4 serve as the virtual ground so that the voltage at the output terminal OT1 is equal to the voltage at the input terminal IN1 in the current mirror circuit 1.

In the embodiment, the operational amplifier 4 controls the voltage at the input terminal IN2 of the current mirror circuit 2A such that the voltage at the output terminal OT1 is equal to the voltage at the input terminal IN1. This can prevent a value of the reference current Iref outputted from the current mirror circuit 2A from being dropped regardless of the low first voltage Vdd1at the first voltage power supply Vdd.

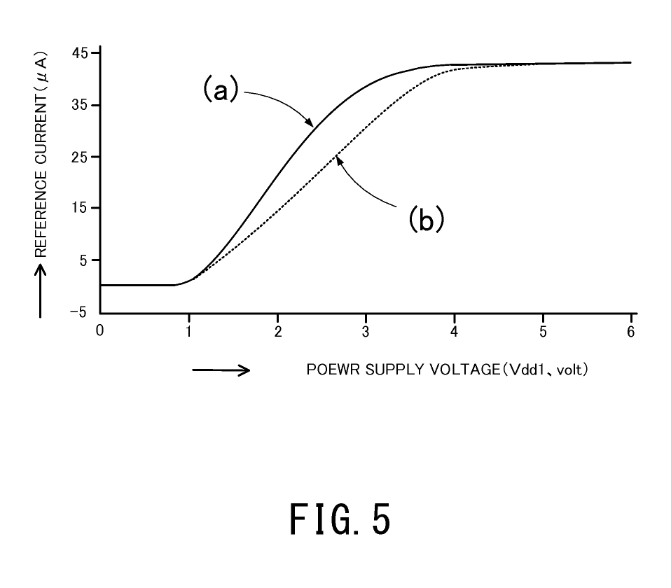

The power supply voltage dependence of an output reference current in the reference current setting circuit will be described with reference to FIG. 5. FIG. 5 is a waveform chart of the power supply voltage dependence, which is obtained by simulation, of an output reference current from the reference current setting circuit. A solid line (a) in the drawing indicates a result, which obtained by simulation, of a relation between the first voltage Vdd1 and the reference current Iref outputted from the reference current setting circuit 91. A dashed line (b) in the drawing indicates a result, which obtained by simulation, of a relation between the first voltage Vdd1 and the reference current Iref outputted from the reference current setting circuit 90 in the first embodiment.

As shown in FIG. 5, when the first voltage Vdd1 is within a low voltage region (for example, a region from 4V to 1V), a larger value of the reference current Iref can be obtained in the embodiment than in the first embodiment.

As described above, the embodiment can prevent a value of the reference current Iref from being dropped regardless of the low first voltage Vdd1.

The reference current setting circuit in at least one of the embodiments explained in the foregoing can prevent an oscillation from being generated regardless of providing an external terminal to connect a resistor.

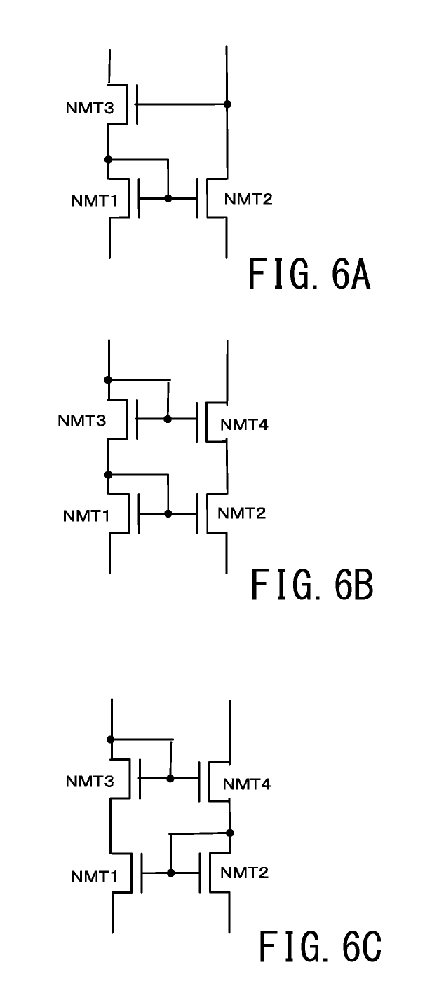

Although the current mirror circuit has a simple configuration in the embodiments, the current mirror circuit is not necessarily limited to the simple configuration. Current mirror circuits in a modification shown in FIGS. 6A to 6C, for example, may be used.

FIG. 6A illustrates a Wilson-type current mirror circuit. As shown in FIG. 6A, the Wilson-type current mirror circuit includes N-channel MOS transistors NMT1 to NMT3. The N-channel MOS transistor NMT1 has a drain that is connected to a gate of the N-channel MOS transistor NMT1 and a gate of the N-channel MOS transistor NMT2. The N-channel MOS transistor NMT3 has a source that is connected to the drain of the N-channel MOS transistor NMT1, and a gate that is connected to a drain of the N-channel MOS transistor NMT2.

FIG. 6B illustrates a cascode-type current mirror circuit. As shown in FIG. 6B, the cascode-type current mirror circuit includes N-channel MOS transistors NMT1 to NMT4. The N-channel MOS transistor NMT1 has a drain that is connected to a gate of the N-channel MOS transistor NMT1 and a gate of the N-channel MOS transistor NMT2. The N-channel MOS transistor NMT3 has a source that is connected to the drain of the N-channel MOS transistor NMT1, and a drain that is connected to a gate of the N-channel MOS transistor NMT3 and a gate of the N-channel MOS transistor NMT4. The N-channel MOS transistor NMT4 has a source that is connected to a drain of the N-channel MOS transistor NMT2.

FIG. 6C illustrates a high-accuracy Wilson-type current mirror circuit. As shown in FIG. 6C, the high-accuracy Wilson-type current mirror circuit includes N-channel MOS transistors NMT1 to NMT4. The N-channel MOS transistor NMT2 has a drain that is connected to a gate of the N-channel MOS transistor NMT1 and a gate of the N-channel MOS transistor NMT2. The N-channel MOS transistor NMT3 has a source that is connected to a drain of the N-channel MOS transistor NMT1, and a drain that is connected to a gate of the N-channel MOS transistor NMT3 and a gate of the N-channel MOS transistor NMT4. The N-channel MOS transistor NMT4 has a source that is connected to the drain of the N-channel MOS transistor NMT2.

The Wilson-type current mirror circuit, the cascode-type current mirror circuit, and the high-accuracy Wilson-type current mirror circuit in the modification can generate a more stable reference current with respect to variations (for example, gate length) or a short gate length of the transistors that constitute the current mirror circuit, compared with the current mirror circuit in the embodiment.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A reference current setting circuit comprising:
a first terminal connected to a ground potential via a first resistor;
a first current mirror circuit including a first transistor with a source connected to a reference voltage and a drain serving as a first input terminal, and a second transistor with a source connected to the first terminal and a drain serving as a first output terminal, the drain of the first transistor being connected to a gate of the first transistor and a gate of the second transistor;
a second current mirror circuit including a second input terminal and second to fourth output terminals, the second input terminal connected to the first output terminal, the second output terminal connected to the first input terminal, the second current mirror circuit configured to be supplied with a first voltage power supply and to output a reference current from the third output terminal; and
a third current mirror circuit including a fifth output terminal connected to the reference voltage source and a third input terminal connected to the fourth output terminal.

2. The reference current setting circuit according to claim 1, wherein a back gate of the first transistor and a back gate of the second transistor are connected to the ground potential.

3. The reference current setting circuit according to claim 2, wherein each of transistors constituting the second current mirror circuit include a back gate and a source both being connected to the first voltage power supply, and
each of transistors constituting the third current mirror circuit include a back gate and a source both being connected to the ground potential.

4. The reference current setting circuit according to claim 1, wherein each of the first transistor and the second transistor is any of an N-channel MOS transistor and an N-channel MIS transistor.

5. The reference current setting circuit according to claim 1, wherein
the second current mirror circuit includes:
a third transistor with a source and a back gate both being connected to the first voltage power supply, and a drain serving as the second input terminal;
a fourth transistor with a source and a back gate both being connected to the first voltage power supply, and a drain serving as the second output terminal;
a fifth transistor with a source and a back gate both being connected to the first voltage power supply, and a drain serving as the third output terminal; and
a sixth transistor with a source and a back gate both being connected to the first voltage power supply, and a drain serving as the fourth output terminal, and
the drain of the third transistor is connected to gates of the third to sixth transistors.

6. The reference current setting circuit according to claim 5, wherein each of the third to sixth transistors is any of a P-channel MOS transistor and a P-channel MIS transistor.

7. The reference current setting circuit according to claim 5, wherein
the third current mirror circuit includes:
a seventh transistor with a source and a back gate both being connected to the ground potential, and a drain serving as the third input terminal; and
an eighth transistor with a source and a back gate both being connected to the ground potential, and a drain serving as the fifth output terminal, and
the drain of the seventh transistor is connected to a gate of the seventh transistor and a gate of the eighth transistor.

8. The reference current setting circuit according to claim 7, wherein each of the seventh transistor and the eighth transistor is any an N-channel MOS transistor and an N-channel MIS transistor.

9. The reference current setting circuit according to claim 1, wherein the first resistor is an externally connected resistor.

10. The reference current setting circuit according to claim 7, wherein a mirror ratio of the first transistor and the second transistor is 1, a mirror ratio of the third transistor and the fourth transistor is 1, a mirror ratio of the third transistor and the fifth transistor is 1, a mirror ratio of the third transistor and the sixth transistor is 1, and a mirror ratio of the seventh transistor and the eighth transistor is 1.

11. The reference current setting circuit according to claim 1, wherein a magnitude of a current flowing through the fifth output terminal of the third current mirror circuit is equal to a magnitude of a current flowing through the reference voltage source from the first current mirror circuit.

12. The reference current setting circuit according to claim 1, further comprising an operational amplifier interposed between the first output terminal of the first current mirror circuit and the second input terminal of the second current mirror circuit.

13. The reference current setting circuit according to claim 12, wherein the operational amplifier includes a non-inverting input terminal connected to the first output terminal of the first current mirror circuit, an inverting input terminal connected to the first input terminal of the first current mirror circuit, and an output terminal connected to the second input terminal of the second current mirror circuit.

14. The reference current setting circuit according to claim 12, wherein the operational amplifier is provided with a phase compensation capacitor.

15. The reference current setting circuit according to claim 1, wherein the first current mirror circuit is any one of a Wilson-type current mirror circuit, a cascode-type current mirror circuit, and a high-accuracy Wilson-type current mirror circuit.
